(19) United States
(12) Patent Application Publication
(10) Pub. No.: US 2009/0014810 A1
(43) Pub. Date: Jan. 15, 2009

(54) METHOD FOR FABRICATING SHALLOW TRENCH ISOLATION AND METHOD FOR FABRICATING TRANSISTOR

(76) Inventors: Eun-Jong Shin, Mapo-gu (KR); Kun-Hyuk Lee, Dohong-gu (KR)

Correspondence Address: SHERR & VAUGHN, PLLC, 620 HERNDON PARKWAY, SUITE 200, HERNDON, VA, 20170, US

(21) Appl. No.: 12/145,305

(22) Filed: Jun. 24, 2008

(30) Foreign Application Priority Data
Jun. 26, 2007 (KR) 10-2007-0063088

(51) Int. Cl. H01L 27/092; H01L 21/762

(52) U.S. Cl. 257/369; 438/425; 257/E21.546; 257/E27.062

(57) ABSTRACT

A method of forming a shallow trench isolation includes sequentially forming a pad oxide layer and a pad nitride layer over a semiconductor substrate. A portion of the pad nitride layer is etched and patterned. The patterned pad nitride layer is used as a etching mask to etch the pad oxide layer and the semiconductor substrate, thus forming a trench. An oxide layer is formed over the surface of the trench by an oxidation process. A barrier liner layer is formed over the oxide layer to create a tensile stress in a vertical direction to the semiconductor substrate. The trench is filled with insulation material and then planarized to expose a top face of the patterned pad nitride layer. A shallow trench isolation structure is completed by removing the patterned pad nitride layer and pad oxide layer. The process prevents a divot effect cased on an edge area of shallow trench isolation structure.

The present application claims priority under 35 U.S.C. 119 to Korean Patent Application No. 10-2007-0063088 (filed on Jun. 26, 2007), which is hereby incorporated by reference in its entirety.

### BACKGROUND

In deep submicron CMOS technology used, for example, in CIS (CMOS Image Sensors), flash memory, SRAM, DRAM, low-power RF devices etc., a shallow trench isolation (STI) structure allows for electrical isolation of individual devices and components. The STI structure controls the threshold and sub-threshold transistor characteristics according to the set of processes chosen. In particular, as the size of semiconductor devices becomes smaller, the STI process may be the most sensitive in semiconductor devices such as SRAM, DRAM, flash memory, and CIS products in which narrow width transistors in a cell apply a relatively strong influence on device characteristics.

### SUMMARY

Embodiments provide a method of forming a shallow trench isolation to prevent a divot effect caused in an edge area of shallow trench isolation. An oxide layer may be formed over a surface of trench through an oxidation process. A barrier liner layer may then be formed, for example, a silicon nitride layer, over a surface of the oxide layer.

Embodiments provide a method of forming a transistor with a tensile strain and a compressive strain structure by providing a tensile stress to NMOS and PMOS areas of a semiconductor substrate through use of a barrier liner layer adapted within a shallow trench isolation. An ion implant process is performed before a formation of a lightly doped drain region (LDD) for the PMOS area to provide a compressive stress to a channel region of the PMOS area.

According to embodiments, a method of forming a shallow trench isolation includes sequentially forming a pad oxide layer and a pad nitride layer over a semiconductor substrate. A portion of the pad nitride layer is etched and patterned. The patterned pad nitride layer is used as a etching mask to etch the pad oxide layer and the semiconductor substrate, thus forming a trench. An oxide layer is formed over the surface of the trench by an oxidation process. A barrier liner layer is formed over the oxide layer to create a tensile stress in a vertical direction to the semiconductor substrate. The trench is filled with insulation material and then planarized to expose a top face of the patterned pad nitride layer. A shallow trench isolation structure is completed by removing the patterned pad nitride layer and pad oxide layer. The process prevents a divot effect cased on an edge area of shallow trench isolation structure.

According to embodiments, a method of forming a transistor includes defining an active area and forming a shallow trench isolation structure to isolate between NMOS and PMOS areas. A gate pattern may be formed over an active area of the NMOS and PMOS areas.

An ion implant process may be performed over the active area of the PMOS area exposed through the gate pattern over the PMOS area to apply a compressive stress to a channel region of the PMOS area. N type and P type lightly doped drain regions may be formed by an impurity ion implantation process. A gate spacer may be formed over a sidewall of the gate pattern. N type and P type source/drain areas may be formed through an impurity ion implantation process.

In the transistor according to embodiments, an oxide layer may be formed over the surface of trench through an oxidation process, and a barrier liner layer as a silicon nitride layer may be formed over the surface of oxide layer. This prevents a divot effect caused on an edge region of the shallow trench isolation structure and simultaneously increases a mobility level of electron carrier about 15%˜20% as compared with a semiconductor device of an unstrained structure in an NMOSFET.

In addition, a divot effect may be prevented by forming a shallow trench isolation structure through use of a barrier liner layer, and a hump effect of a narrow width transistor caused by a divot is improved, thereby stably controlling characteristics of sub threshold and threshold area.

According to embodiments, a mechanically strained Si structure caused by a tensile stress is provided through a barrier liner layer, thereby increasing an electron mobility on a channel region of NMOSFET and realizing CMOS devices of low power and high performance.

In a transistor according to embodiments, a tensile stress is provided to NMOS and PMOS areas of a semiconductor substrate by using a barrier line layer formed in the shallow trench isolation structure, and an ion implantation process is performed before forming LDD for the PMOS area to provide a compressive stress to a channel region of PMOS area, thereby compensating a reduction of hole mobility on the PMOS area through a formation of the barrier liner layer.

### DRAWINGS

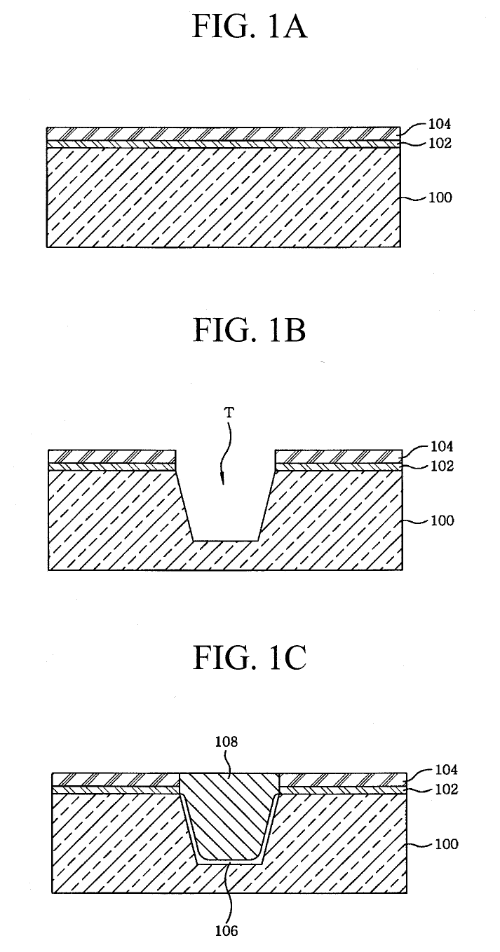

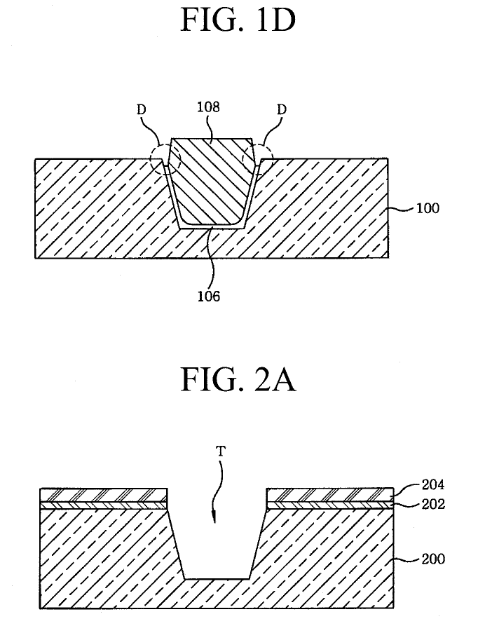

Example FIGS. 1A to 1D are sectional views illustrating steps of forming a shallow trench isolation according to embodiments.

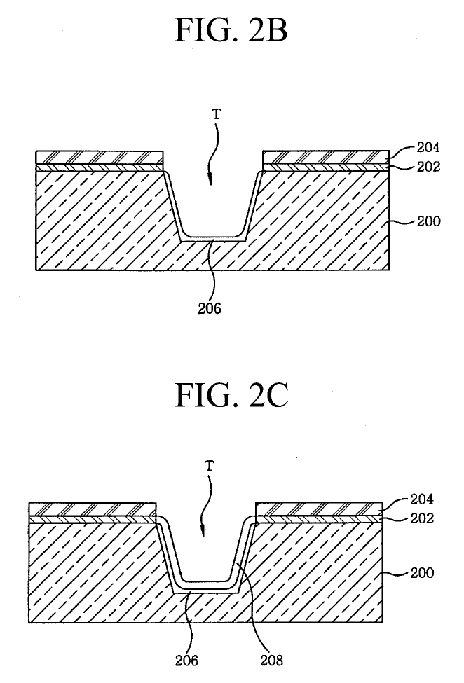

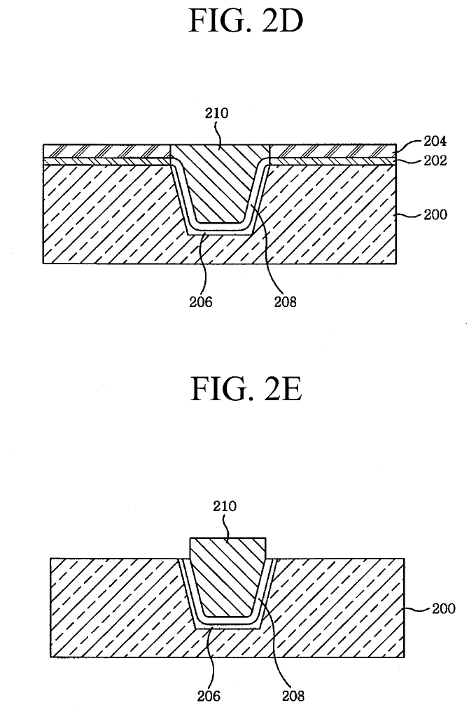

Example FIGS. 2A to 2E are sectional views illustrating formation steps of shallow trench isolation according to embodiments.

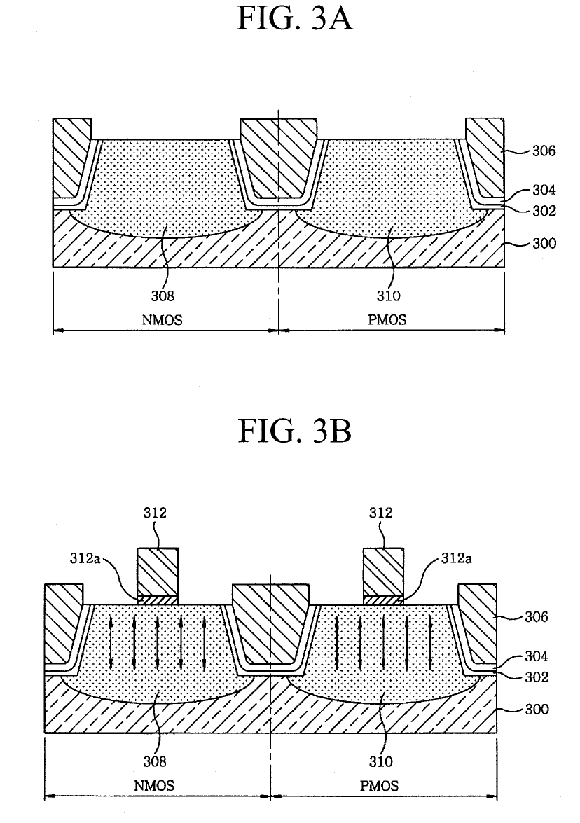

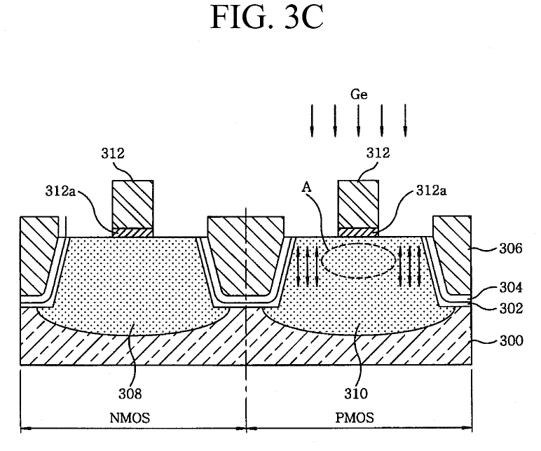

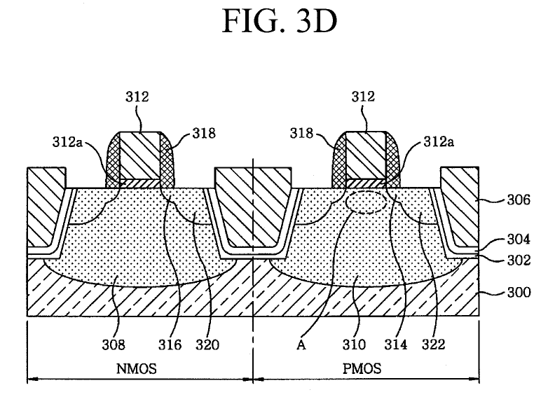

Example FIGS. 3A to 3D are sectional views illustrating transistor formation steps according to embodiments.

### DESCRIPTION

Hereinafter, a shallow trench isolation formation process is described according to embodiments, referring to the accompanied drawings. Example FIGS. 1A to 1D are sectional views illustrating steps of forming a shallow trench isolation according to embodiments.

As shown in example FIG. 1A, a pad oxide layer 102 and a pad nitride layer 104 are sequentially formed over a semiconductor substrate 100 through, for example, a chemical vapor deposition (CVD) process. Then, as shown in example FIG. 1B, an entire face of the pad nitride layer 104 is covered with photoresist. A photoresist pattern may be formed through an exposure and developing process using a mask that defines an active area. Thus, a photoresist pattern is formed only over the pad nitride layer 104 of an active area. The pad nitride layer 104 may be patterned by performing a dry etching process using the photoresist pattern as an etch mask. Then, the photoresist pattern is removed. Semiconductor substrate 100 may be etched a given depth, for example, about 2500 Å to about 2700 Å, by performing a reactive ion etching process that uses the patterned pad nitride layer 104 as a hard mask, thereby forming a trench T.

Then, as shown in example FIG. 1C, an oxide layer 106 with a thickness of about 100 Å is formed over the trench by an oxidation process. A formation process of the oxide layer 106 reduces a stress in the trench (T) surface generated in an etching process and simultaneously repairs damage done to the trench surface in the reactive ion etching process.

Subsequently, an HDP (High Density Plasma)-CVD process may be performed to completely fill in the trench with, for example, USG. Chemical mechanical polishing (CMP) may be performed to expose the surface of the patterned pad nitride layer 104, thus forming a shallow trench isolation structure 108.

Then, as shown in example FIG. 1D, the patterned pad nitride layer 104 and the pad oxide layer 102 are removed. In an exemplary removal process of the pad nitride layer 104 and the pad oxide layer 102, a wet etching and HF cleaning process using H₃PO₄ at 150° C. may be performed, thereby removing the patterned pad nitride layer 104 and the pad oxide layer 102.

However, in a related shallow trench isolation formation process described above, an excessive oxide recess may be generated at a corner part of active area during the HF cleaning process. This may cause a divot D on an edge region of the shallow trench isolation. A well voltage of a corner portion of the active area may be lowered by such divot D. A hump characteristic, in which a transistor may begin to conduct a sub threshold voltage, may be caused by a divot D in a narrow width transistor. Such hump characteristics may cause an error in a threshold characteristic of narrow width transistors constituting a cell. This may become a critical factor in producing errors in cell operations.

Example FIGS. 2A to 2E are sectional views illustrating steps of shallow trench isolation in a semiconductor device according to embodiments. With reference to example FIG. 2A, a pad oxide layer 202 and a pad nitride layer 204 are sequentially formed over a semiconductor substrate 200 through CVD. The pad oxide layer 202 may be about 55 Å˜65 Å thick, and the pad nitride layer 204 may be about 900 Å˜1100 Å thick. The pad nitride layer 204 will be used as a polishing stop layer in forming a shallow trench isolation described below. In the semiconductor substrate 200 according to embodiments, a P-well may be formed in the inside thereof to form an NMOSFET.

A photoresist pattern to define a device isolation region is formed over the pad nitride layer 204 through photolithography process. That is, an upper part of pad nitride layer 204 is covered with photoresist, and a photoresist pattern is formed by performing an exposure and developing process using a mask that defines an active area. Thus, photoresist pattern is formed only over the pad nitride layer 204 of active area, and the pad nitride layer 204 is patterned through a dry etching process by using the photoresist pattern as an etching mask, and then the photoresist pattern is removed through a strip process.

Then, the semiconductor substrate 200 is etched a given depth, i.e., 2500 Å˜2700 Å, by performing a reactive ion etching process that uses the patterned pad nitride layer 204 formed through such steps as a hard mask, thereby forming trench T.

Then, as shown in example FIG. 2B, an oxidation process is performed to form an oxide layer 206 having a thickness of about 150 Å˜200 Å over the surface of trench T. At this time, the formation process of oxide layer 206 alleviate a stress of the trench (T) surface and simultaneously recovers a damage of the trench (T) surface generated by a reactive ion etching process.

The oxidation process according to embodiments is performed in an oxygen (O₂) atmosphere at 950° C.˜1050° C., for example at a temperature of 1000° C. At this temperature, or range of temperatures, dislocation effects can be prevented. Dislocation effects occur when stress is induced in an interface of the semiconductor substrate 200 by the stress between a barrier liner layer formed over the surface of the oxide layer 206 in a subsequent process, and the oxide layer 206.

Then, as shown in example FIG. 2C, barrier liner layer 208 is formed over the surface of the oxide layer 206. The barrier liner layer 208 may be formed, for example, in an LP-CVD (Low Pressure Chemical Vapor Deposition) in a temperature range of 700° C.˜800° C., with a thickness of 400 Å˜450 Å. The barrier layer may be formed from silicon nitride, for example. The liner layer 208 may have a tensile strength stronger than the oxide layer 206.

As described above, the barrier liner layer 208 is formed by LP-CVD in a temperature range of 700° C.˜800° C., and thus a tensile stress is created in a direction vertical to a channel region in the semiconductor substrate 200. That is, the barrier liner layer 208 applies a vertical tensile stress to the semiconductor substrate 200. Therefore, mobility of electron carriers in the semiconductor substrate 200 may be improved.

As shown in example FIG. 2D, the HDP-CVD process is performed to fully fill in the trench, and insulation material, for example, USG, fills in the trench T. The chemical mechanical polishing (CMP) process may be performed with the patterned pad nitride layer 204 as a polishing stop point, thereby forming a shallow trench isolation structure 210.

Subsequently, as shown in example FIG. 2E, a wet etching process using H₃PO₄ at temperature of 150° C. and HF cleaning process are sequentially performed to remove the patterned pad nitride layer 204 and the pad oxide layer 202, thereby forming a shallow trench isolation structure 210.

In a semiconductor device having the shallow trench isolation structure 210 according to embodiments, oxide layer 206 is formed over the surface of the trench T through an oxidation process, and then a barrier liner layer 208 as a silicon nitride layer is formed over the surface of the oxide layer 206, thereby preventing divot effect caused on an edge region of shallow trench isolation 210. Additionally, in NMOSFET, electron carrier mobility can be increased about 15%˜20% as compared with a semiconductor device having an unstrained structure.

In other words, a divot effect is prevented and a mobility of electron carriers is enhanced since a tensile stress is formed along a vertical direction to a channel region in the semiconductor substrate 200. Therefore a hump effect of a narrow width transistor is improved and sub threshold and threshold area characteristics are enhanced. Furthermore, a semiconductor substrate with a mechanically strained Si structure can be formed.

Example FIGS. 3A to 3D are sectional views illustrating steps of forming a MOS transistor using a shallow trench isolation formation process according to embodiments. Through a series of steps as shown in example FIGS. 2A to 2E, a semiconductor substrate 300 is divided into an NMOS area having a P-well 308 and a PMOS area having an N-well 310 in an asymmetrical structure. A shallow trench isolation structure 306 defining an active area is formed over NMOS and PMOS. Inside the shallow trench isolation 306, a thin film oxide layer 302 and a barrier liner layer 304 are formed over a portion in contact with the semiconductor substrate 300.

In forming the shallow trench isolation structure 306, channel regions of the NMOS and PMOS areas have a vertical tensile stress created by a barrier liner layer 304 formed over the surface of oxide layer 302, for example, a silicon nitride layer. This tensile stress improves mobility of electrons in the NMOS area. On the other hand, mobility of holes falls in the PMOS area.

As shown in 3B, over the active area of NMOS area and PMOS area, gate insulation material and a conductive layer for a formation of gate electrode, for example, a polysilicon layer, is formed. These layers are etched to form a gate insulation layer 312a and gate electrode 312, thereby forming each gate pattern over the NMOS area and the PMOS area.

As shown in example FIG. 3C, photoresist pattern for a formation of P-type LDD exposing only a PMOS area may be formed. An ion implantation process to realize a compressive stress for the PMOS area may be performed. Here, the ion implantation process may be a germanium (Ge) ion implantation process using ion energy of 20 keV at a dose of 10¹⁴˜10¹⁵ as an example.

The interior of semiconductor substrate 300 exposed by the gate electrode 312 in the PMOS area for the exemplary Ge ion implantation process has a tensile stress in a vertical direction. Thus, channel region A of the PMOS area has a relatively weak compressive stress. Accordingly, mobility of charge carrier holes in the channel region A of the PMOS area can be improved. In other words, channel region A of the PMOS area becomes more compressive as compared with a channel region of the NMOS area. Therefore, the channel region of the NMOS area has an improved electron mobility, and the channel region A of the PMOS area has an improved hole mobility.

As shown in example FIG. 3D, a P-type LDD 314 is formed by performing a P-type impurity ion implantation process. A photoresist pattern may be used for the formation of P-type LDD as an ion implantation mask. Thereafter, the photoresist pattern for the formation of P-type LDD may be removed through a strip process.

A photoresist pattern selectively exposing only the NMOS area may be formed. N-type impurity ions are implanted to form an N-type LDD 316. Then, photoresist pattern formed over the PMOS area is removed by performing a strip process.

An insulation layer for a spacer is deposited over the whole surface. An entire surface etching process is performed. A gate spacer 318 is formed in both sidewalls of gate pattern over the NMOS area and the PMOS area.

Subsequently, a photoresist pattern selectively exposing only an NMOS area may be formed and then N-type impurity may be ion implanted by using a gate pattern and a gate spacer 318 as a mask, thereby forming an N-type source/drain area 320. Then, the photoresist pattern may be removed by performing a strip process.

After that, a photoresist pattern selectively exposing only an PMOS area may be formed. P-type impurity ions may be implanted by using a gate pattern and a gate spacer 318 as a mask, thereby forming an P-type source/drain area 322. Then, the photoresist pattern may be removed through a strip process.

Through a series of processes described above, as shown in example FIG. 3D, N-type source/drain area 320 having a structure of N-type LDD 316 may be formed over the NMOS area, and over the PMOS area, P-type source/drain area 322 having P-type LDD structure 318 may be formed. According to embodiments, an ion implantation process is performed before forming an LDD in the PMOS area, thereby compensating a reduction of hole mobility in the PMOS area due to a tensile stress generated on an active area of semiconductor substrate 300 through barrier liner layer 304 formed over the surface of oxide layer 302.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a pad oxide layer over a semiconductor substrate;
forming a pad nitride layer over the pad oxide layer;
etching a portion of the pad nitride layer to form a patterned pad nitride layer;
etching the pad oxide layer and the semiconductor substrate, using the patterned pad nitride layer as a etching mask, to form a trench;
forming an oxide layer over the surface of the trench;
forming a barrier liner layer over the oxide layer to form a tensile stress along a vertical direction with respect to the semiconductor substrate;
filling the trench with insulation material;
performing a planarization process to expose a top face of the patterned pad nitride layer; and
removing the patterned pad nitride layer and pad oxide layer.

2. The method of claim 1, wherein the oxide layer is formed with a thickness of 150 Å˜250 Å.

3. The method of claim 1, wherein the oxide layer is formed at temperature of 950° C.˜1,050° C.

4. The method of claim 1, wherein the barrier liner layer is a silicon nitride layer formed by a low pressure chemical vapor deposition process.

5. The method of claim 3, wherein the barrier liner layer is formed with a thickness of 400 Å˜500 Å.

6. The method of claim 3, wherein the barrier liner layer is formed at a temperature range of 700° C.˜800° C.

7. The method of claim 1, wherein the semiconductor substrate is an NMOS substrate with a P-type well.

8. A method comprising:
defining an active area;
forming a shallow trench isolation structure to isolate between NMOS and PMOS areas;
forming a gate pattern over an active area of the NMOS and PMOS areas;
performing an ion implant process over the active area of the PMOS area exposed through the gate pattern over the PMOS area to apply a compressive stress to a channel region of the PMOS area;
forming N type and P type lightly doped drain regions by performing an impurity ion implantation process thereon;
forming a gate spacer over a sidewall of the gate pattern; and
forming N type and P type source/drain areas through an impurity ion implantation process.

9. The method of claim 8, wherein the forming the shallow trench isolation structure comprises:
forming a trench by selectively etching the semiconductor substrate;
forming the oxide layer by performing an oxidation process for the surface of the trench;
forming a barrier liner layer over the surface of the oxide layer to provide a tensile stress on the active area of the PMOS and NMOS areas;
filling the trench with insulation material; and
performing a planarization process to expose a top face of the patterned pad nitride layer.

10. The method of claim 9, wherein the oxide layer is formed with a thickness of about 150 Å˜250 Å.

11. The method of claim 10, wherein the oxide layer is formed at temperature of 950° C.˜1,050° C.

12. The method of claim 9, wherein the barrier liner layer is a silicon nitride layer formed through an low pressure chemical vapor deposition process.

13. The method of claim 9, wherein the barrier liner layer is formed with a thickness of about 400˜500 Å.

14. The method of claim 9, wherein the barrier liner layer is formed at a temperature range of 700° C.˜800° C.

15. The method of claim 8, wherein the ion implantation process performed on the active area of the PMOS area uses germanium ions.

16. An apparatus comprising:
a semiconductor substrate over which NMOS areas and PMOS areas are formed;
a shallow trench isolation structure defining an active area over the NMOS and PMOS areas, and including an oxide layer formed within a trench formed over the semiconductor substrate and a barrier liner layer formed on the oxide layer;
a first gate electrode formed on the active area of the PMOS area;
a first channel region formed under the first gate electrode; and
source/drain areas having implanted material providing a compressive stress to the first channel region.

17. The apparatus of claim 16, wherein the barrier liner layer is formed of silicon nitride and has a tensile strength stronger than a tensile strength of the oxide layer.

18. The apparatus of claim 17, wherein the barrier liner layer provides a tensile stress to the PMOS area and the NMOS area along a vertical direction with respect to the semiconductor substrate.

19. The apparatus of claim 16, wherein the transistor comprises:
a second gate electrode formed over the active area of the NMOS area; and
a second channel area formed under the second gate electrode, the first channel region under a greater compressive stress than the second channel region.

20. The apparatus of claim 16, wherein the implanted material to provide the compressive stress to the first channel area is germanium.
